(19) United States
(12) Patent Application Publication
(10) Pub. No.: US 2011/0049580 A1
(43) Pub. Date: Mar. 3, 2011

(54) Hybrid Packaged Gate Controlled Semiconductor Switching Device Using GaN MESFET

(76) Inventors: Sik Lui, Sunnyvale, CA (US); Anup Bhalla, Santa Clara, CA (US)

(21) Appl. No.: 12/550,230

(22) Filed: Aug. 28, 2009

(51) Int. Cl. H01L 27/088; H01L 21/98; H01L 23/52

(52) U.S. Cl. 257/262; 438/109; 438/121; 257/E27.061; 257/E23.141; 257/E21.705

(57) ABSTRACT

A hybrid packaged gate controlled semiconductor switching device (HPSD) has an insulated-gate transistor (IGT) made of a first semiconductor die and a rectifying-gate transistor (RGT) made of a second semiconductor die. The RGT gate and source are electrically connected to the IGT source and drain respectively. The HPSD includes a package base with package terminals for interconnecting the HPSD to external environment. The IGT is die bonded atop the package base. The second semiconductor die is formed upon a composite semiconductor epi layer overlaying an electrically insulating substrate (EIS) thus creating a RGT die. The RGT die is stacked and bonded atop the IGT die via the EIS. The IGT, RGT die and package terminals are interconnected with bonding wires. Thus, the HPSD is a stacked package of IGT die and RGT die with reduced package footprint while allowing flexible placements of device terminal electrodes on the IGT.

### CROSS REFERENCE TO RELATED APPLICATIONS

This application is related to the following patent applications that are incorporated herein by reference for any and all proposes:

U.S. application Ser. No. 11/830,951 entitled “A Multi-die DC-DC Boost Power Converter with Efficient Packaging” by Francois Hebert et al with filing date of Jul. 31, 2007, hereinafter referred to as U.S. Ser. No. 11/830,951.

U.S. application Ser. No. 11/830,996 entitled “A Multi-die DC-DC Buck Power Converter with Efficient Packaging” by Francois Hebert et al with filing date of Jul. 31, 2007, hereinafter referred to as U.S. Ser. No. 11/830,996.

U.S. application Ser. No. 12/391,251 entitled “Compact Power Semiconductor Package and Method with Stacked Inductor and Integrated Circuit Die” by Tao Feng et al with filing date of Feb. 23, 2009, hereinafter referred to as U.S. Ser. No. 12/391,251.

U.S. application Ser. No. 12/397,473 entitled “Compact Inductive Power Electronics Package” by Tao Feng et al with filing date of Mar. 4, 2009, hereinafter referred to as U.S. Ser. No. 12/397,473.

### FIELD OF INVENTION

This invention relates generally to the field of electrical circuit. More specifically, the present invention is directed to the physical level packaging of an electrical switching circuit.

### BACKGROUND OF THE INVENTION

In addition to a technically sound basic circuit design, modern day electronics frequently demand high quality and efficient packaging at the physical level. This is especially so in portable applications where compact package size, low EMI/RFI (electromagnetic interference/radio frequency interference) and flexibility of system configuration are all highly important considerations.

U.S. Pat. No. 5,396,085 entitled “Silicon carbide switching device with rectifying-gate” by Baliga, hereinafter referred to as U.S. Pat. No. 5,396,085, disclosed a silicon carbide switching device that includes a three-terminal interconnected silicon MOSFET and silicon carbide MESFET (or JFET) in a composite substrate of silicon and silicon carbide. For convenience, FIG. 5A, FIG. 5B, FIG. 6 and FIG. 7 of U.S. Pat. No. 5,396,085 are reproduced herein respectively as FIG. A1, FIG. A2, FIG. B1 and FIG. B2.

Thus, FIG. A1 schematically illustrates an electrical schematic of a three-terminal silicon carbide switching device with rectifying-gate 10. The three-terminal switching device 10 comprises an insulated-gate field effect transistor 12 (shown as a Si MOSFET) having a first source region 14, a first drain region 16 and an insulated-gate electrode 18. The insulated gate field effect transistor 12 is preferably an enhancement-mode device which is nonconductive at zero potential gate bias (shown by dotted lines). Accordingly, conduction in the transistor 12 typically requires the formation of an inversion layer channel in the transistor's active region. Alternatively, the transistor 12 may also be an ACCU-FET, which is preferably designed to be nonconductive at zero potential gate bias. A rectifying-gate field effect transistor 22 (shown as a SiC MESFET), having a second source region 24, a second drain region 26 and a rectifying-gate electrode 28 is also provided, connected to the insulated-gate field effect transistor 12, as shown. Source and drain contacts 20 and 30, respectively, are also provided. Accordingly, electrical connection to the three terminal device is provided by the insulated-gate electrode 18, the source contact 20 and the drain contact 30. FIG. A2 schematically illustrates a three-terminal silicon carbide switching device with rectifying-gate 10′. The three-terminal switching device 10′ comprises a rectifying-gate field effect transistor 22′ (shown as a SiC JFET), having a second source region 24′, a second drain region 26′ and a rectifying-gate electrode 28′, connected to the insulated-gate field effect transistor 12, as shown.

To facilitate the formation of the three-terminal switching devices 10 and 10′ of FIG. A1 and FIG. A2, a composite semiconductor substrate 48 having regions of both SiC and Si may be used. In particular, FIG. B1 and FIG. B2 are respectively cross-sectional representations of the switching devices of FIG. A1 and FIG. A2 using the composite semiconductor substrate 48.

It is remarked that, with the composite substrate of silicon and silicon carbide, the flexibility of device structural configuration of both switching devices 10 and 10′ can be constrained by materials and process compatibility at the silicon-silicon carbide interface. This constraint can be exacerbated by the demand of an overall compact package size of the switching devices 10 and 10′. Another concern associated with the silicon-silicon carbide composite substrate is the potential of increased device leakage current due to molecular level structural defects at the silicon-silicon carbide interface. It is therefore desirable to develop alternative packaging schemes for the three-terminal switching devices to avoid these constraint and concern while keeping the overall package compact.

### SUMMARY OF THE INVENTION

A hybrid packaged 3-terminal gate controlled semiconductor switching device (HPSD) is proposed. The HPSD has an interconnected insulated-gate transistor (IGT) made of a first semiconductor die and a rectifying-gate transistor (RGT) made of a second semiconductor die located atop an electrically insulating substrate (EIS). The RGT device terminal electrodes are located at front surface of the second semiconductor die with the RGT gate electrode and source electrode electrically connected to the IGT source electrode and drain electrode respectively. The HPSD includes:
A package base having numerous package terminals for interconnecting the HPSD to its external environment.
The IGT die bonded atop the package base.
A RGT die located atop an electrically insulating substrate (EIS) upon which a composite semiconductor epitaxial layer is formed for the fabrication of the RGT device. In turn, the RGT die is stacked and bonded atop the IGT die via the EIS.
A variety of interconnectors for interconnecting the IGT die, the RGT die and the package terminals.

As a result, the HPSD becomes a stacked package of IGT die and RGT die with reduced package footprint while allowing larger die sizes and flexible placements of device terminal electrodes on the IGT die.

In a more specific embodiment, the IGT is an enhancement mode Metal-Oxide-Semiconductor Field Effect Transistor (MOSFET).

In a particular device structural configuration, the enhancement mode MOSFET is a bottom drain MOSFET with its drain electrode located on its bottom surface but its source and gate electrodes located on its top surface.

More specifically, the package base can be made of a leadframe, a multi-layer circuit laminate or a chip-on-lead package and the bottom drain MOSFET die can be flip-chip bonded onto the chip-on-lead package.

In another particular device structural configuration, the enhancement mode MOSFET is a bottom source MOSFET with its source electrode located on its bottom surface but its gate and drain electrodes located on its top surface.

In a more specific embodiment, the RGT is a depletion mode metal semiconductor field effect transistor (MESFET).

In a more specific embodiment, the first semiconductor die is made of silicon (Si), germanium (Ge), gallium arsenide (GaAs) or silicon-germanium (SiGe) and the second semiconductor die is made of gallium nitride (GaN).

In a more specific embodiment, the EIS is sapphire, diamond, zinc oxide (ZnO), aluminum nitride (AlN) or semi-insulating SiC. When the EIS is sapphire the GaN can be grown on the EIS.

In a more detailed embodiment, the RGT die can be bonded atop the IGT die via die attach using insulating epoxy or non-insulating epoxy.

In a more detailed embodiment, the RGT die further includes an evaporated back metal and the RGT die can be bonded atop the IGT die via die attach using solder.

These aspects of the present invention and their numerous embodiments are further made apparent, in the remainder of the present description, to those of ordinary skill in the art.

### BRIEF DESCRIPTION OF THE DRAWINGS

In order to more fully describe numerous embodiments of the present invention, reference is made to the accompanying drawings. However, these drawings are not to be considered limitations in the scope of the invention, but are merely illustrative.

FIG. A1 illustrates an electrical schematic of a first three-terminal silicon carbide switching device with rectifying-gate of the prior art U.S. Pat. No. 5,396,085;

FIG. B1 is the cross-sectional representation of the switching device of FIG. A1 using a composite semiconductor substrate;

FIG. A2 illustrates an electrical schematic of a second three-terminal silicon carbide switching device with rectifying-gate of the prior art U.S. Pat. No. 5,396,085;

FIG. B2 is the cross-sectional representation of the switching device of FIG. A2 using a composite semiconductor substrate;

FIG. 1 is a perspective illustration of a rectifying-gate transistor die of the present invention;

FIG. 2A is a perspective illustration of a first device structural configuration of a hybrid packaged 3-terminal gate controlled semiconductor switching device under the present invention; and

FIG. 2B is a perspective illustration of a second device structural configuration of a hybrid packaged 3-terminal gate controlled semiconductor switching device under the present invention.

### DETAILED DESCRIPTION OF SPECIFIC EMBODIMENTS

The description above and below plus the drawings contained herein merely focus on one or more currently preferred embodiments of the present invention and also describe some exemplary optional features and/or alternative embodiments. The description and drawings are presented for the purpose of illustration and, as such, are not limitations of the present invention. Thus, those of ordinary skill in the art would readily recognize variations, modifications, and alternatives. Such variations, modifications and alternatives should be understood to be also within the scope of the present invention.

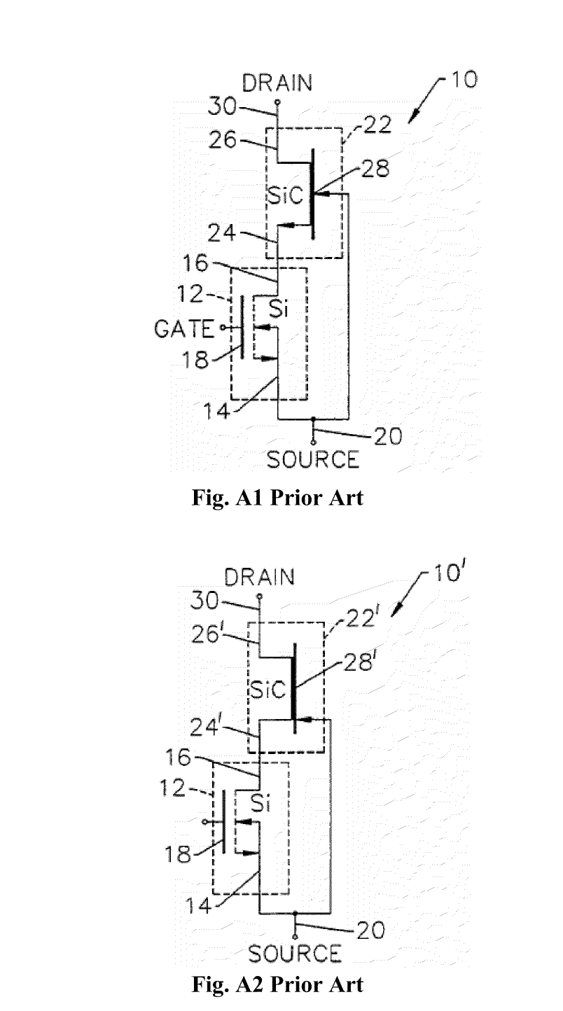

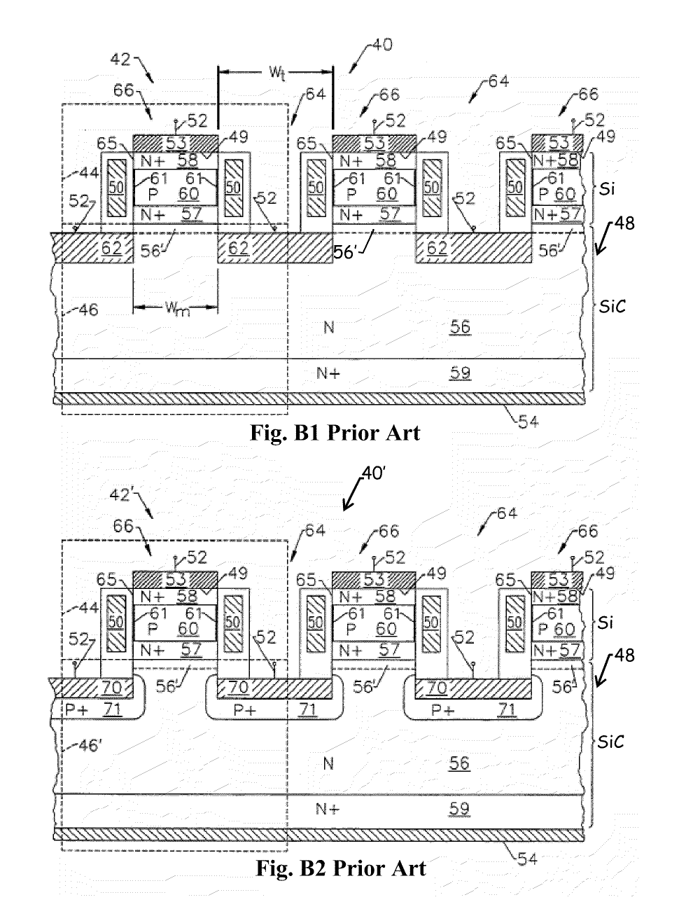

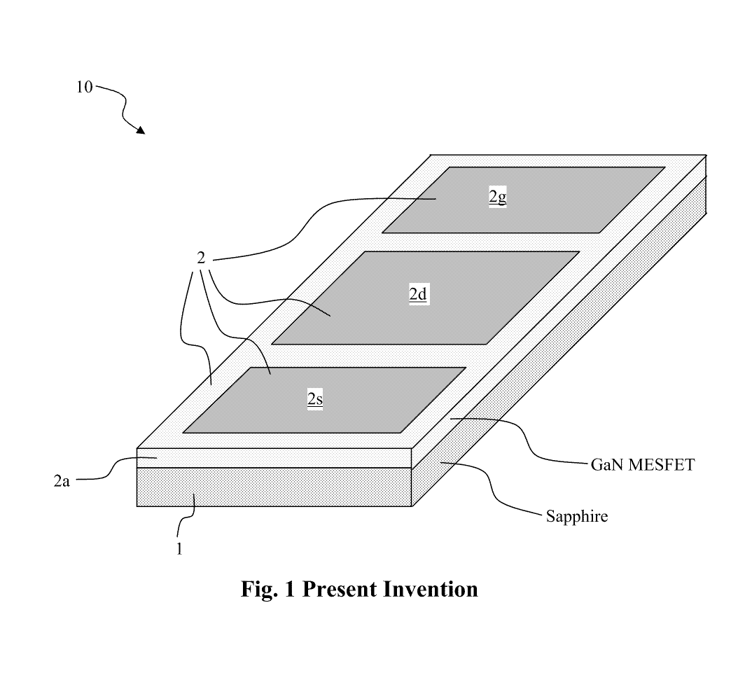

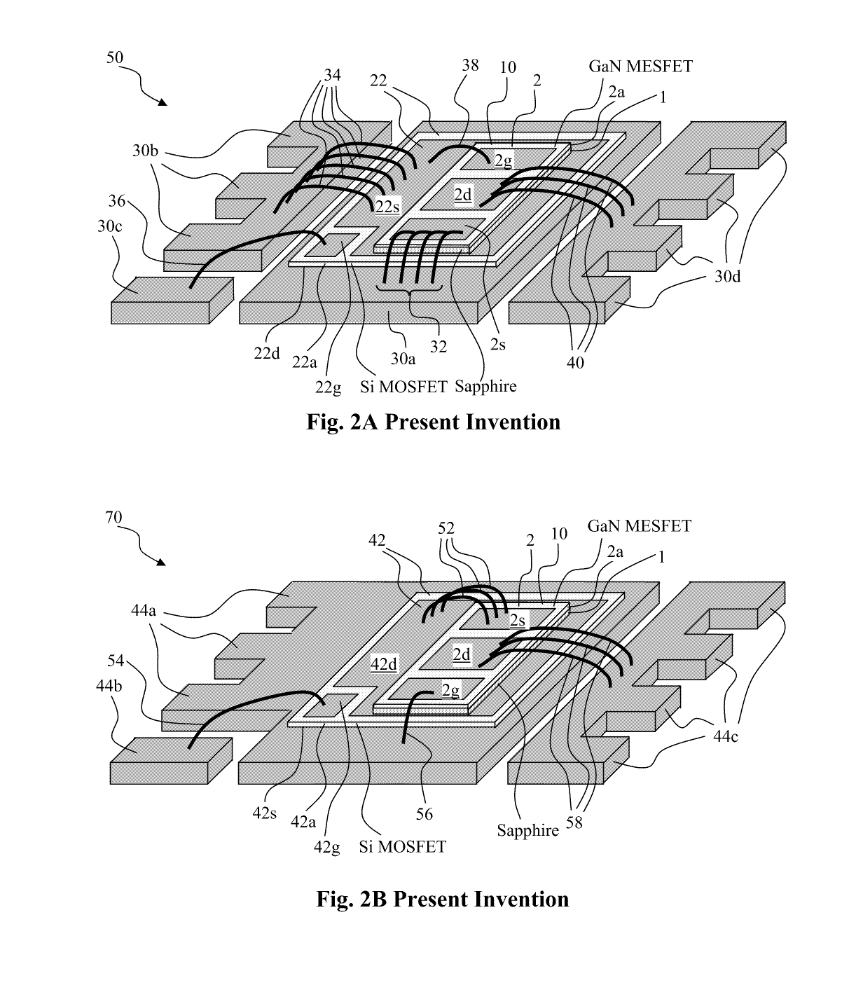

FIG. 1 together with FIG. 2A are perspective illustrations of a first device structural configuration of a hybrid packaged 3-terminal gate controlled semiconductor switching device (HPSD) 50, together with a rectifying-gate transistor (RGT) die 10, under the present invention.

The HPSD 50 has a package base that, in this case, includes numerous leadframe sections 30a, 30b, 30c and 30d. Each of the leadframe sections 30b, 30c and 30d has a plurality of package terminals for interconnecting the HPSD 50 to its external environment. Bonded atop the package base (leadframe section 30a) is a silicon Metal-Oxide-Semiconductor Field Effect Transistor (MOSFET) made of a silicon semiconductor die 22 with a silicon semiconductor substrate 22a. Thus, the leadframe section 30a also acts as the main heat sink of the HPSD 50. In particular, the silicon MOSFET can be an enhancement mode vertical MOSFET. A GaN (gallium nitride) Metal-Semiconductor Field Effect Transistor (MESFET) made of a separate semiconductor die 2 has a GaN semiconductor epitaxial layer 2a formed upon a sapphire substrate 1 to create a GaN rectifying-gate transistor (RGT) die 10 (FIG. 1). Owing to materials and process compatibility, the GaN epitaxial layer 2a can be grown on the sapphire substrate 1. In particular, the GaN MESFET can be a depletion mode lateral MESFET. The device terminal electrodes MESFET drain 2d, MESFET source 2s and MESFET gate 2g of the GaN MESFET are all located at its front surface. In this case, the silicon vertical MOSFET is a bottom drain MOSFET with its MOSFET drain 22d electrode located on its bottom surface but its MOSFET source 22s and MOSFET gate 22g electrodes located on its top surface.

The RGT die 10 is in turn stacked and bonded, via the sapphire substrate 1, atop the silicon semiconductor die 22. As sapphire is an electrically insulating material, bonding of the RGT die 10 atop the silicon semiconductor die 22 can be via die attach using either an insulating epoxy or a non-insulating epoxy. In another embodiment, a metal can be evaporated onto the back side of the RGT die 10 followed by die attaching it atop the silicon semiconductor die 22 using a solder material. In case a semi-insulating material such as SiC is used as the substrate to grow the GaN epitaxial layer, proper insulation between the RGT substrate and the MOSFET die is required. The HPSD 50 also has numerous bonding wires 32, 34, 36, 38 and 40 for electrically interconnecting the silicon MOSFET, the RGT die 10 and the package terminals. Thus, the MESFET gate 2g electrode is connected to the MOSFET source 22s electrode via bonding wires 38. The MESFET source 2s is connected to the MOSFET drain 22d electrode via bonding wires 32. The MOSFET source 22s is connected to the leadframe section 30b via bonding wires 34. The MOSFET gate 22g is connected to the leadframe section 30c via bonding wires 36. The MESFET drain 2d is connected to the leadframe section 30d via bonding wires 40. As configured, the HPSD 50 constitutes a 3-terminal enhancement mode device (as opposed to a depletion mode device). Being an enhancement mode device is important in that its application environment is compatible with that of the most popular MOSFET which are enhancement mode devices that normally remain off but only turned on upon an applied gate voltage. If so desired, the HPSD 50 can be configured to be compatible with standard pin-outs of the most popular MOSFET as well.

The stacked package of silicon semiconductor die 22 and GaN semiconductor die 2 provides the advantages of a reduced HPSD 50 package footprint while allowing larger individual die sizes for a correspondingly reduced drain-source resistance R_{DS}. As a particular example, an R_{DS} of 1 milliOhm to 2 milliOhm can be achieved for the Si MOSFET and an RDS of 5 milliOhm to 10 milliOhm can be achieved for the GaN MESFET. Additionally, to be presently illustrated, the usage of the electrically insulating sapphire substrate 1 on the RGT die 10 allows flexible placements of device terminal electrodes on the silicon semiconductor die 22.

FIG. 1 together with FIG. 2B are perspective illustrations of a second device structural configuration of an HPSD 70, together with its RGT die 10, under the present invention. The HPSD 70 has a package base that includes numerous leadframe sections 44a, 44b and 44c each having a plurality of package terminals for interconnecting the HPSD 70 to its external environment. Bonded atop the package base (leadframe section 44a) is a silicon vertical MOSFET made of a silicon semiconductor die 42 with a silicon semiconductor substrate 42a. Thus, the leadframe section 44a, which functions as an electric terminal of the package, also acts as the main heat sink of the HPSD 70.

Except for the silicon semiconductor die 42 being a bottom source device with its MOSFET source 42s electrode located on its bottom surface and its gate and drain electrodes 42g and 42d located on its top surface thus isolated from the package base, the rest constituents of the HPSD 70 are similar to those of the HPSD 50. Thus, the MESFET gate 2g electrode is connected to the MOSFET source 42s electrode via bonding wires 56. The MESFET source 2s is connected to the MOSFET drain 42d electrode via bonding wires 52. The MOSFET source 42s is bonded to the leadframe section 44a. The MOSFET gate 42g is connected to the leadframe section 44b via bonding wires 54. The MESFET drain 2d is connected to the leadframe section 44c via bonding wires 58.

While the main switching node (MOSFET drain 22d) of the HPSD 50 was electrically shorted to its main heat sink (leadframe section 30a), the main switching node (MOSFET drain 42d) of the HPSD 70 is electrically isolated from its main heat sink (leadframe section 44a). Thus, comparing with the HPSD 50, the device structural configuration of HPSD 70 provides an advantage of a correspondingly reduced EMI/RFI emission.

An HPSD is described under the present invention. While the HPSD has been described using a RGT die 10 with a sapphire substrate 1, other electrically insulating materials such as diamond, zinc oxide (ZnO), aluminum nitride (AlN), or semi-insulating SiC can be used as the substrate as well. With references made to U.S. Ser. No. 11/830,951, U.S. Ser. No. 11/830,996, U.S. Ser. No. 12/391,251 and U.S. Ser. No. 12/397,473, by now it should become clear to those skilled in the art that the present invention can also be practiced with the following alternatives:
The package base made of a printed circuit board (PCB).
The package base made of a chip-on-lead package with the bottom drain silicon semiconductor die 22 flip-chip bonded with solder balls onto the chip-on-lead package.
The bonding wires replaced with three dimensionally formed interconnection plates.
   Additionally, in general the silicon MOSFET can be replaced with a variety of insulated-gate transistors (IGT) made of silicon (Si), germanium (Ge), gallium arsenide (GaAs) or silicon-germanium (SiGe).

While the description above contains many specificities, these specificities should not be constructed as accordingly limiting the scope of the present invention but as merely providing illustrations of numerous presently preferred embodiments of this invention. It will be appreciated by those of ordinary skill in the art that the present invention can be embodied in numerous other specific forms and those of ordinary skill in the art would be able to practice such other embodiments without undue experimentation. The scope of the present invention, for the purpose of the present patent document, is hence not limited merely to the specific exemplary embodiments of the foregoing description, but rather is indicated by the following claims. Any and all modifications that come within the meaning and range of equivalents within the claims are intended to be considered as being embraced within the spirit and scope of the present invention.

What is claimed are:

1. A hybrid packaged 3-terminal gate controlled semiconductor switching device (HPSD) having an interconnected insulated-gate transistor (IGT) made of a first semiconductor die and a rectifying-gate transistor (RGT) made of a second semiconductor die having a composite semiconductor layer wherein the device terminal electrodes of the RGT are located at its front surface with its gate electrode and source electrode electrically connected to the IGT source electrode and drain electrode respectively, the HPSD comprises:
a package base having a plurality of package terminals for interconnecting the HPSD to its external environment;
the IGT die bonded atop the package base;
an electrically insulating substrate (EIS) upon which the composite semiconductor layer is formed creating a RGT die that is in turn stacked and bonded, via the EIS, atop the IGT die;
an interconnecting means for interconnecting the IGT, the RGT die and the package terminals
whereby making the HPSD a stacked package of IGT die and RGT die with reduced package footprint while allowing larger die sizes and flexible placements of device terminal electrodes on the IGT die.

2. The HPSD of claim 1 wherein said IGT is a Metal-Oxide-Semiconductor Field Effect Transistor (MOSFET).

3. The HPSD of claim 2 wherein said MOSFET is a bottom drain MOSFET with its drain electrode located on its bottom surface but its source and gate electrodes located on its top surface.

4. The HPSD of claim 3 wherein said package base is a chip-on-lead package and the bottom drain MOSFET die is flip-chip bonded onto the chip-on-lead package.

5. The HPSD of claim 2 wherein said MOSFET is a bottom source MOSFET with its source electrode located on its bottom surface, whereas its gate and drain electrodes located on its top surface thus isolated from the package base.

6. The HPSD of claim 1 wherein said RGT is a metal semiconductor field effect transistor (MESFET).

7. The HPSD of claim 6 wherein said MESFET is a depletion mode MESFET.

8. The HPSD of claim 1 wherein said first semiconductor die is made of silicon (Si), germanium (Ge), gallium arsenide (GaAs) or silicon-germanium (SiGe).

9. The HPSD of claim 1 wherein said composite semiconductor layer is made of gallium nitride (GaN).

10. The HPSD of claim 9 wherein said EIS is sapphire, diamond, zinc oxide (ZnO), aluminum nitride (AlN) or semi-insulating SiC.

11. The HPSD of claim 9 wherein said EIS is sapphire and the GaN is grown on the sapphire.

12. The HPSD of claim 1 wherein bonding of the RGT die atop the IGT die is via die attach using insulating epoxy or non-insulating epoxy.

13. The HPSD of claim 1 wherein said RGT die further comprises an evaporated back metal and bonding of the RGT die atop the IGT die is via die attach using solder.

14. The HPSD of claim 9 wherein said first semiconductor die is made of silicon.

15. The HPSD of claim 14 wherein said first semiconductor is an enhancement mode device, and said second semiconductor is a depletion mode device.

16. A method of forming a hybrid packaged 3-terminal gate controlled semiconductor switching device (HPSD) having an interconnected insulated-gate transistor (IGT) made of a first semiconductor die and a rectifying-gate transistor (RGT) made of a second semiconductor die having a composite semiconductor layer wherein the device terminal electrodes of the RGT are located at its front surface with its gate electrode and source electrode electrically connected to the IGT source electrode and drain electrode respectively, the method comprises:
providing a package base having a plurality of package terminals for interconnecting the HPSD to its external environment;
bonding the IGT die atop the package base;
providing an electrically insulating substrate (EIS) and forming the composite semiconductor layer upon it to create a RGT die;
stacking and bonding the RGT die, via the EIS, atop the IGT die; and
interconnecting the IGT, the RGT die and the package terminals
whereby making the HPSD a stacked package of IGT die and RGT die with reduced package footprint while allowing larger die sizes and flexible placements of device terminal electrodes on the IGT die.

17. The method of claim 16 wherein said package base is a chip-on-lead package, said IGT is a bottom drain MOSFET and bonding the IGT die further comprises flip-chip bonding the bottom drain MOSFET die onto the chip-on-lead package.

18. The method of claim 16 wherein bonding the RGT die further comprises bonding it using insulating epoxy or non-insulating epoxy.

19. The method of claim 16 wherein creating the RGT die further comprises evaporating a back metal onto the EIS and bonding the RGT die further comprises bonding it using a solder.

20. The method of claim 16 wherein said EIS is made of sapphire.

21. The method of claim 20 wherein the second semiconductor die is a depletion mode device made of gallium nitride (GaN), forming the composite semiconductor layer comprises of growing the GaN on the sapphire and the first semiconductor die is an enhancement mode device.
